(19) United States
(12) Patent Application Publication
(10) Pub. No.: US 2007/0131947 A1
(43) Pub. Date: Jun. 14, 2007

(54) Light-emitting device

(75) Inventor: Sang Hoon Han, Gwangju (KR)

Correspondence Address: BIRCH STEWART KOLASCH & BIRCH, PO BOX 747, FALLS CHURCH, VA, 22040-0747, US

(73) Assignee: LG INNOTEK CO., LTD

(21) Appl. No.: 11/637,138

(22) Filed: Dec. 12, 2006

(30) Foreign Application Priority Data
Dec. 13, 2005 (KR) 10-2005-012370

(51) Int. Cl. H01L 33/00

(52) U.S. Cl. 257/86

(57) ABSTRACT

A light-emitting device is provided. The light-emitting device includes a first conductive cladding layer, an active layer, a second conductive cladding layer, a second conductive electrode, and a short block barrier. The first conductive cladding layer is on a substrate. The active layer is on the first conductive cladding layer. The second conductive cladding layer is on the active layer. The second conductive electrode is on the second conductive cladding layer. The short block barrier is formed on either side of the second conductive electrode.

### BACKGROUND OF THE INVENTION

1. Field of the Invention

The invention relates to a light-emitting device and a nitride semiconductor light-emitting device.

2. Description of the Related Art

In general, a light-emitting diode (LED) is a type of semiconductor light-emitting device. The LED is a device that uses the characteristics of a compound semiconductor device to convert an electric signal to infrared rays, visible radiation, or light, to send and receive signals.

Applications for LEDs include home appliances, remote controllers, electronic display boards, display devices, and various automated devices. LEDs can be largely divided into infrared emitting diodes (IRED) and visible light-emitting diodes (VLED).

In order to directly mount miniaturized LEDs on printed circuit boards (PCB), they are formed in a surface mount device configuration. Accordingly, LEDs that are used as display devices are also being developed in the surface mount device configuration. These surface mount devices can replace conventional lamps, and can be used in light display devices, character display devices, and image display devices, etc. to display a wide range of colors.

As the applications for light-emitting devices increase, and brightness requirements for household lighting, rescue signal lighting, etc. increase, development of high-output light-emitting devices is being conducted.

Referring to the diagrams, a description of light-emitting devices according to the related art will be given.

FIG. 1 is a sectional view of a light-emitting device according to the related art.

Referring to FIG. 1, a light-emitting device according to the related art includes a substrate 10 on which a buffer layer 20, an undoped gallium nitride layer 30, an N-type cladding layer 40, an active layer 50, and a P-type cladding layer 60 are sequentially formed.

Moreover, a P-type electrode 90 is formed on the P-type cladding layer 60, and an N-type electrode 80 is formed on a side of the surface of the N-type cladding layer 40.

However, in a fabrication process of a light-emitting device according to the related art, due to the miniaturizations of chips, gaps separating the P-type electrodes 90 and the N-type electrodes 80 are reduced, leading to frequent short circuiting.

### SUMMARY OF THE INVENTION

Accordingly, the invention is related to a light-emitting device that substantially obviates one or more problems due to limitations and disadvantages of the related art.

The embodiment of the invention provides a light-emitting device and a manufacturing method thereof capable of preventing short circuits between P-type electrodes and N-type electrodes.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

In an embodiment of the invention, there is provided a light-emitting device including: a first conductive cladding layer on a substrate; an active layer on the first conductive cladding layer; a second conductive cladding layer on the active layer; a second conductive electrode on the second conductive cladding layer; and a short block barrier formed on either side of the second conductive electrode.

In another aspect embodiment of the invention, there is provided a light-emitting device including: a first conductive cladding layer on a substrate; an active layer on the first conductive cladding layer; a second conductive cladding layer on the active layer; a first conductive electrode on a portion of the first conductive cladding layer; and a short block barrier formed on either side of the first conductive electrode.

In further aspect embodiment of the invention, there is provided a light-emitting device including: a first conductive cladding layer on a substrate; an active layer on the first conductive cladding layer; a second conductive cladding layer on the active layer; a second conductive electrode on the second conductive cladding layer; a first conductive electrode on a portion of the first conductive cladding layer; a first short block barrier formed on either side of the first conductive electrode; and a second short block barrier formed on either side of the second conductive electrode.

It is to be understood that both the foregoing general description and the following detailed description of the invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is a sectional view of a light-emitting device according to the related art;

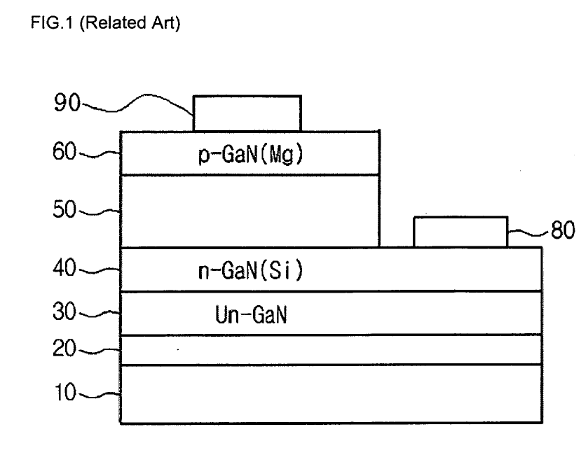

FIG. 2 is a sectional view of a light-emitting device according to the first embodiment of the present invention;

FIG. 3 is plan view of a light-emitting device according to the first embodiment of the present invention;

FIG. 4 is a sectional view of a light-emitting device according to the second embodiment of the present invention;

FIG. 5 is a sectional view of a light-emitting device according to the third embodiment of the present invention; and

FIG. 6 is a plan view of a light-emitting device according to the third embodiment of the present invention.

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

In the descriptions of the embodiments according to the present invention, when a layer is said to be formed “on” another layer, this may denote that the layer is formed directly on the other layer or formed indirectly thereon, with intervening layers formed between.

Also, while the description of the embodiments of the present invention is of a light-emitting device that is a nitride semiconductor device formed of 3 and 5 groups of compound materials including gallium nitride (GaN), aluminum nitride (AlN), indium nitride (InN), from which gallium nitride is applied, the present invention is not limited thereto.

### First Embodiment

Below, a detailed description will be given of a light-emitting device according to the first embodiment of the present invention, with reference to the drawings.

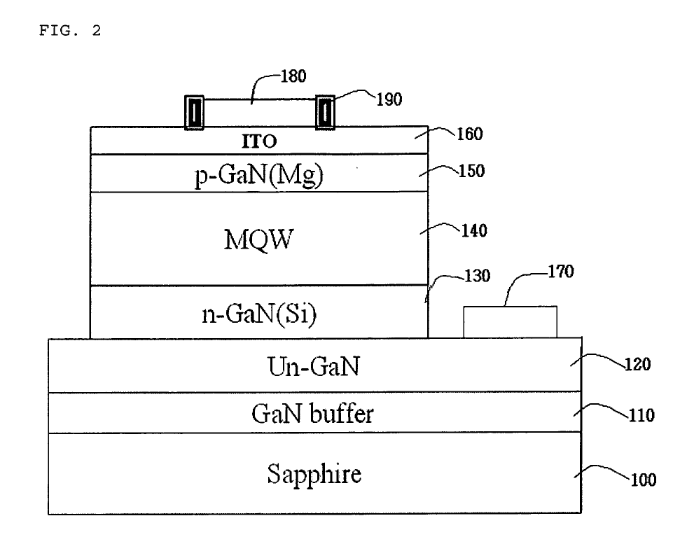

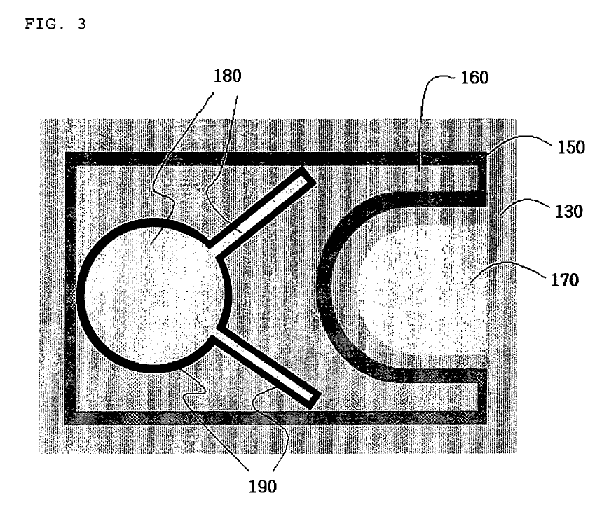

FIG. 2 is a sectional view of a light-emitting device according to the first embodiment of the present invention, and FIG. 3 is plan view of a light-emitting device according to the first embodiment of the present invention.

Referring to FIGS. 2 and 3, the light-emitting device according to the first embodiment of the present invention includes a substrate 100 on which a buffer layer 110 is formed, an undoped gallium nitride layer 120, a first conductive cladding layer 130, an active layer 140, a second conductive cladding layer 150, a transparent ohmic electrode 160, a first conductive electrode 170, and a second conductive electrode 180.

Here, the first conductive cladding layer 130 is an N-type layer, and the second conductive cladding layer 150 is a P-type layer; however, this embodiment is not restricted thereto. That is, the first conductive cladding layer 130 may be a P-type layer, and the second conductive cladding layer 150 may be an N-type layer.

The buffer layer 110 is formed on the substrate 100, whereby it increases the flatness of the substrate 100 to grow a fine quality nitride. Accordingly, melt-back etching due to the chemical reaction of the substrate can be prevented.

Also, the N-type cladding layer 130 is grown on the undoped gallium 120, so that the N-type cladding layer 130 may function as a base layer for the nitride semiconductor light-emitting device.

For example, the N-type cladding layer 130 may be an N-type gallium nitride layer doped with a silicon (Si) dopant.

Further, the active layer 140 is formed on the N-type cladding layer 130.

The active layer 140 is a layer with a multi quantum well (MQW) structure that emits light by coupling the holes moving through the P-type electrode 180 and the electrons moving through the N-type electrode 170.

Next, the P-type cladding layer 150 is formed on the active layer 140, and the P-type electrode 180 is formed on the P-type cladding layer 150.

For example, the P-type cladding layer 150 may be formed as a 3-5 group semiconductor of a gallium nitride doped with a magnesium (Mg) dopant.

Here, the transparent ohmic electrode 160 is further formed on the P-type cladding layer 150, forming the P-type electrode 180. For example, the P-type cladding layer 150 may further include a transparent ohmic electrode 160 formed of indium-tin oxide (ITO) on the P-type cladding layer 150, to form the P-type electrode 180.

Then, regions of the P-type cladding layer 150 that do not have the P-type electrode formed thereon, and a portion of the active layer 140 are etched to expose the N-type cladding layer 130. Here, the N-type cladding layer 130 may be partially etched.

Next, an N-type electrode 170 is formed on the exposed N-type cladding layer 130.

Then, a second short block barrier (SBB) 190 is formed on the surrounding region of the P-type electrode 180.

Here, the second SBB 190 is formed after the forming of the P-type electrode 180, but is not restricted thereto. For example, the second SBB 190 may be formed before the P-type electrode 180 is formed.

Also, the second SBB 190 is formed after the forming of the N-type electrode 170, but is not restricted thereto. For example the second SBB 190 may be formed before the forming of the N-type electrode 170.

The second SBB 190 is formed between the N-type electrode 170 and the P-type electrode 180 to prevent short circuits in the electrodes.

The second SBB 190 may be formed to enclose the P-type electrode 180 on both sides thereof, as shown in FIG. 3.

For example, as shown in FIG. 3, the P-type electrode 180 can include electrode having two branches such as the form of antennae extending toward the N-type electrode, in which case the second SBB 190 may be formed to enclose the sides of the P-type electrode 180 with the exception of its upper and lower surfaces.

The second SBB 190 is formed of an insulating material to prevent short circuits of the electrodes. For example, the second SBB 190 may be formed of an oxide layer to effectively prevent short circuits between electrodes.

Also, the second SBB 190 may be formed of a silicon nitride SiN₃ or similar insulating material to effectively prevent short circuits between electrodes.

Furthermore, the second SBB 190 may be formed through chemical vapor deposition (CVD), physical vapor deposition (PVD), or sputtering.

In the light-emitting device according to the first embodiment of the present invention, when a voltage is applied from the N-type electrode 170 to the P-type electrode 180, electrons flow from the N-type cladding layer 130 to the active layer 140, and holes move from the P-type cladding layer 150 to the active layer 140. Here, the electrons and holes moving to the active layer 140 region reattach to generate light.

According to the first embodiment of the present invention, the second SBB 190 prevents the occurrence of short circuits between electrodes due to narrower gaps between the P-type electrode 180 and the N-type electrode 170 due to the recent trend of miniaturizing light-emitting devices.

### Second Embodiment

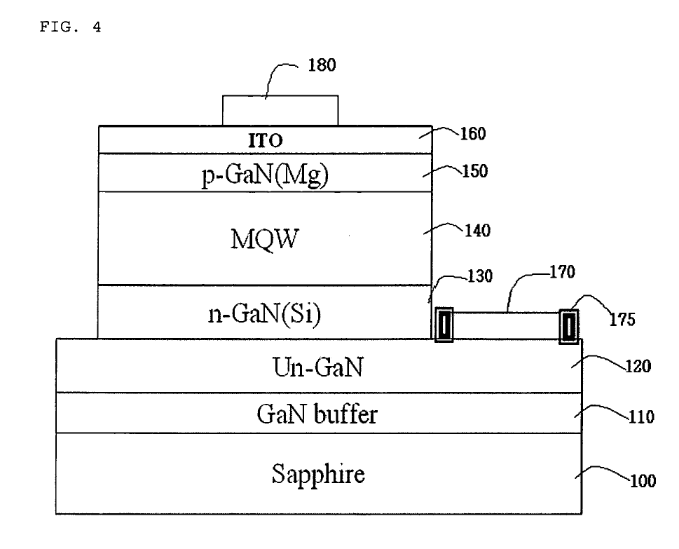

FIG. 4 is a sectional view of a light-emitting device according to the second embodiment of the present invention.

The light-emitting device according to the second embodiment of the present invention, unlike in the first embodiment, includes a first SBB 175 formed on either side of the first conductive electrode 170.

The light-emitting device according to the second embodiment of the present invention may employ the components of the first embodiment.

For example, the first short block barrier (SBB) 175 may be formed around the N-type electrode 170.

Here, the first SBB 175 is formed after the forming of the N-type electrode 170, but is not restricted thereto. For example the first SSB 175 may be formed before the N-type electrode 170 is formed.

The first SBB 175 may be formed to surround the N-type electrode 170 on either side thereof, as shown in FIG. 4.

For example, as shown in FIG. 4, the first SBB 175 may enclose the N-type electrode 170 on all sides except for the upper and lower surfaces.

The first SBB 175 is formed of an insulating material to prevent short circuits from occurring between electrodes. For example, the first SBB 175 may be formed of an insulating material such as silicon nitride SiN₃ to effectively prevent short circuits between electrodes.

According to the second embodiment of the present invention, the second SBB 175 prevents the occurrence of short circuits between electrodes due to narrower gaps between the P-type electrode 180 and the N-type electrode 170 due to the recent trend of miniaturizing light-emitting devices.

### Third Embodiment

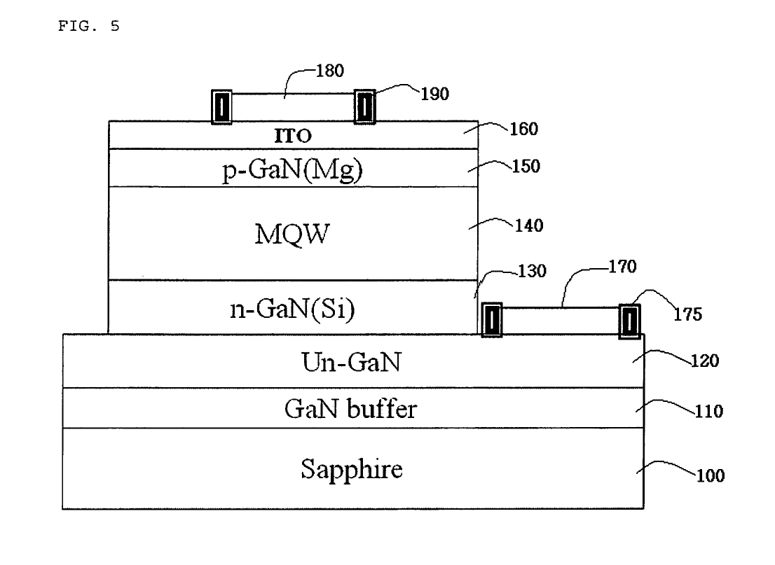

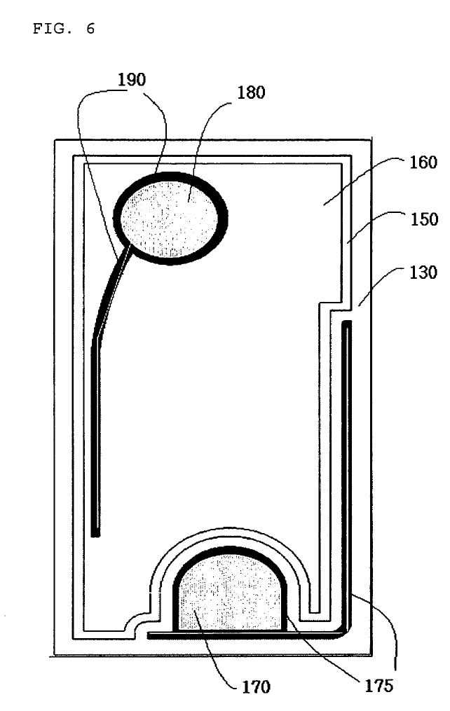

FIG. 5 is a sectional view of a light-emitting device according to the third embodiment of the present invention, and FIG. 6 is a plan view of a light-emitting device according to the third embodiment of the present invention.

A light-emitting device according to the third embodiment of the present invention, unlike in the first embodiment, includes a second SBB 190 and a first SBB 175 formed respectively on either side of a second conductive electrode 180 and a first conductive electrode 170.

The light-emitting device according to the third embodiment of the present invention may employ components of the first embodiment.

The first SBB 175 and the second SBB 190 may be formed respectively to enclose either side of the N-type electrode 170 and the P-type electrode 180, as shown in FIG. 6.

The first and second SBBs 175 and 190 may be formed of an insulating material such as silicon nitride SiN₃ to effectively prevent short circuits between electrodes.

According to the third embodiment of the present invention, the first and second SBBs 175 and 190 prevent the occurrence of short circuits between electrodes due to narrower gaps between the P-type electrode 180 and the N-type electrode 170 due to the recent trend of miniaturizing light-emitting devices.

The light-emitting device according to the embodiments of the present invention is formed with gallium nitride, but is not limited thereto. For example, the light-emitting device according to the present invention may be a nitride semiconductor device using 3 and 5 groups of compound materials including gallium nitride (GaN), aluminum nitride (AlN), and indium nitride (InN).

As described above, the light-emitting device according to the embodiments of the present invention forms a short block barrier on either side of the P-type electrode, the N-type electrode, or the P-type electrode and the N-type electrode, so that short circuits occurring between the P-type and N-type electrodes (which are positioned closer together due to the trend of miniaturization) can be prevented, producing a device with improved reliability.

It will be apparent to those skilled in the art that various modifications and variations can be made in the present invention. Thus, it is intended that the present invention covers the modifications and variations of this invention provided they come within the scope of the appended claims and their equivalents.

What is claimed is:

1. A light-emitting device comprising:
a first conductive cladding layer on a substrate;
an active layer on the first conductive cladding layer;
a second conductive cladding layer on the active layer;
a second conductive electrode on the second conductive cladding layer; and
a short block barrier formed on either side of the second conductive electrode.

2. The light-emitting device according to claim 1, wherein the short block barrier is formed to enclose the second conductive electrode.

3. The light-emitting device according to claim 1, wherein the short block barrier is formed to enclose the second conductive electrode on all surfaces thereof except for top and bottom surfaces.

4. The light-emitting device according to claim 1, wherein the short block barrier is on the second conductive cladding layer.

5. The light-emitting device according to claim 1, wherein the second conductive electrode comprises at least one antenna-shaped conductive electrode.

6. The light-emitting device according to claim 1, wherein the short block barrier is formed of an insulating material.

7. The light-emitting device according to claim 6, wherein the insulating material is an oxide layer.

8. A light-emitting device comprising:
a first conductive cladding layer on a substrate;
an active layer on the first conductive cladding layer;
a second conductive cladding layer on the active layer;
a first conductive electrode on a portion of the first conductive cladding layer; and
a short block barrier formed on either side of the first conductive electrode.

9. The light-emitting device according to claim 8, wherein the short block barrier is formed to enclose the first conductive electrode.

10. The light-emitting device according to claim 8, wherein the short block barrier is formed to enclose the first conductive electrode on all surfaces thereof except for top and bottom surfaces.

11. The light-emitting device according to claim 8, wherein the short block barrier is on the first conductive cladding layer.

12. The light-emitting device according to claim 8, wherein the first conductive electrode comprises at least one antenna-shaped conductive electrode.

13. The light-emitting device according to claim 8, wherein the short block barrier is formed of an insulating material.

14. The light-emitting device according to claim 13, wherein the insulating material is an oxide layer.

15. A light-emitting device comprising:
a first conductive cladding layer on a substrate;
an active layer on the first conductive cladding layer;
a second conductive cladding layer on the active layer;
a second conductive electrode on the second conductive cladding layer;
a first conductive electrode on a portion of the first conductive cladding layer;
a first short block barrier formed on either side of the first conductive electrode; and
a second short block barrier formed on either side of the second conductive electrode.

16. The light-emitting device according to claim 15, wherein the first short block barrier and the second block barrier respectively enclose the first conductive electrode and the second conductive electrode.

17. The light-emitting device according to claim 15, wherein the first short block barrier and the second short block barrier respectively enclose all surfaces of the first conductive electrode and the second conductive electrode, except for top and bottom surfaces of the first and second conductive electrodes.

18. The light-emitting device according to claim 15, wherein the first short block barrier is on the first conductive cladding layer, and the second short block barrier is on the second conductive clad barrier.

19. The light-emitting device according to claim 15, wherein the first short block barrier and the second short block barrier are formed of an insulating material.

20. The light-emitting device according to claim 19, wherein the insulating material is an oxide layer.
